(19) United States
(12) Patent Application Publication
(10) Pub. No.: US 2015/0108555 A1
(43) Pub. Date: Apr. 23, 2015

(54) METHOD OF MANUFACTURING IMAGE SENSORS

(71) Applicant: Samsung Electronics Co., Ltd., Suwon-si (KR)

(72) Inventors: Young-Woo Jung, Yongin-si (KR); Jung-Chak Ahn, Yongin-si (KR); Hee-Geun Jeong, Suwon-si (KR)

(73) Assignee: Samsung Electronics Co., Ltd., Suwon-si (KR)

(21) Appl. No.: 14/294,413

(22) Filed: Jun. 3, 2014

(30) Foreign Application Priority Data
Oct. 23, 2013 (KR) 10-2013-0126449

(51) Int. Cl. H01L 27/146; H01L 29/66; H01L 21/265; H01L 31/18

(52) U.S. Cl. CPC H01L 27/14612; H01L 31/18; H01L 29/66666; H01L 21/26586
USPC 257/290; 438/59

(57) ABSTRACT

In a method of manufacturing an image sensor, a photodiode is formed in a substrate. The substrate is etched to form an opening vertically aligned with the photodiode. A gate insulation layer and a first preliminary polysilicon layer are formed on an inner surface of opening and a front surface of substrate. A first doping process is performed on first preliminary polysilicon layer to form first polysilicon layer, and the first polysilicon layer in the opening is uniformly doped with first conductivity type impurities. A second preliminary polysilicon layer is formed on first polysilicon layer. A second doping process is performed on second preliminary polysilicon layer to form second polysilicon layer doped with first conductivity type impurities. The first and second polysilicon layers are patterned to form a buried gate electrode in the opening. The first impurity region is formed at an upper portion of substrate adjacent to buried gate electrode.

### CROSS-REFERENCE TO RELATED APPLICATION

This application claims priority under 35 USC §119 to Korean Patent Application No. 10-2013-0126449, filed on Oct. 23, 2013 in the Korean Intellectual Property Office (KIPO), the contents of which are herein incorporated by reference in their entirety.

### BACKGROUND

1. Field

Exemplary embodiments in accordance with principles of inventive concepts relate to image sensors and the manufacture thereof. Exemplary embodiment exemplary embodiment

2. Description of the Related Art

An image sensor may be a semiconductor device that may change an optical signal incident thereon into an electrical signal in order to generate electronic image information corresponding to the optical signal. A backside illumination (BSI) image sensor may include a vertical transmission gate transistor and may transfer a large amount of light into a unit pixel of the BSI image sensor.

### SUMMARY

In exemplary embodiments in accordance with principles of inventive concepts, a method of manufacturing an image sensor includes forming a photodiode in a substrate; etching a portion of the substrate to form an opening vertically aligned with the photodiode; forming a gate insulation layer and a first preliminary polysilicon layer on an inner surface of the opening and a front surface of the substrate; performing a first doping process on the first preliminary polysilicon layer to form a first polysilicon layer, a portion of the first polysilicon layer in the opening being uniformly doped with impurities of a first conductivity type; forming a second preliminary polysilicon layer on the first polysilicon layer; performing a second doping process on the second preliminary polysilicon layer to form a second polysilicon layer, the second polysilicon layer being doped with impurities of the first conductivity type; patterning the first and second polysilicon layers to form a buried gate electrode in the opening; and forming a first impurity region at an upper portion of substrate adjacent to the buried gate electrode.

In exemplary embodiments in accordance with principles of inventive concepts a method includes a first doping process that includes a plurality of implantation processes having different implantation angles with respect to a bottom surface of the opening.

In exemplary embodiments in accordance with principles of inventive concepts a method includes a first doping process that includes a first ion implantation process and a second ion implantation process, and wherein a first portion of the first preliminary polysilicon layer is implanted at a first implantation angle by the first ion implantation process, and a second portion of the first preliminary polysilicon layer is implanted at a second implantation angle by the second ion implantation process.

In exemplary embodiments in accordance with principles of inventive concepts a method includes a first doping process performed by a plasma assisted implantation process.

In exemplary embodiments in accordance with principles of inventive concepts a method includes a bottom surface of the opening is spaced apart from a top surface of the photodiode.

In exemplary embodiments in accordance with principles of inventive concepts a method includes forming a leakage prevention impurity region in the substrate by implanting impurities of a second conductivity type opposite to the first conductivity type into a portion of the substrate under the opening.

In exemplary embodiments in accordance with principles of inventive concepts a method includes prior to performing the first doping process, forming an ion implantation mask on the first preliminary polysilicon layer, the ion implantation mask exposing a portion of the first preliminary polysilicon layer over the opening.

In exemplary embodiments in accordance with principles of inventive concepts a method includes performing an annealing process to diffuse the impurities of the first conductive type doped in the first and second polysilicon layers.

In exemplary embodiments in accordance with principles of inventive concepts a method includes patterning the first and second polysilicon layers including forming a gate electrode on the front surface of the substrate.

In exemplary embodiments in accordance with principles of inventive concepts a method includes forming second impurity regions at upper portions of the substrate adjacent to the gate electrode.

In exemplary embodiments in accordance with principles of inventive concepts a method includes a second doping process including a single implantation process.

In exemplary embodiments in accordance with principles of inventive concepts a method includes a second doping process performed by a plasma assisted implantation process.

In exemplary embodiments in accordance with principles of inventive concepts a method includes impurities not doped into a portion of the substrate under a bottom surface of the opening in the first doping process.

In exemplary embodiments in accordance with principles of inventive concepts a method includes impurities are not doped into a portion of the substrate under the front surface of the substrate in the second doping process.

In exemplary embodiments in accordance with principles of inventive concepts a method includes after forming a first impurity region, forming an insulating interlayer to cover the buried gate electrode on the substrate; forming wirings in the insulating interlayer; and sequentially forming a color filter and a microlens on a rear surface of the substrate, wherein the rear surface of the substrate is vertically opposite to the front surface of the substrate.

In exemplary embodiments in accordance with principles of inventive concepts a back side illumination CMOS image sensor includes a microlens formed on a substrate; a photo sensor formed in the substrate to receive electrical signals in response to light received through the microlens; and a vertical channel transmission gate transistor to transfer electrical signals from the photo sensor, the vertical channel including first and second polysilicon layers formed in an opening aligned with the photo sensor, the first and second polysilicon layers having been implanted with impurities in separate processing steps.

In exemplary embodiments in accordance with principles of inventive concepts a back side illumination CMOS image sensor includes a first polysilicon layer that has been implanted from a plurality of angles.

In exemplary embodiments in accordance with principles of inventive concepts a back side illumination CMOS image sensor includes a first polysilicon layer that has been implanted using a plasma assisted ion doping process.

In exemplary embodiments in accordance with principles of inventive concepts an electrical system includes a back side illumination CMOS image sensor that includes a microlens formed on a substrate; a photo sensor formed in the substrate to receive electrical signals in response to light received through the microlens; and a vertical channel transmission gate transistor to transfer electrical signals from the photo sensor, the vertical channel including first and second polysilicon layers formed in an opening aligned with the photo sensor, the first and second polysilicon layers having been implanted with impurities in separate processing steps.

In exemplary embodiments in accordance with principles of inventive concepts a smart phone includes a back side illumination CMOS image sensor that includes a microlens formed on a substrate; a photo sensor formed in the substrate to receive electrical signals in response to light received through the microlens; and a vertical channel transmission gate transistor to transfer electrical signals from the photo sensor, the vertical channel including first and second polysilicon layers formed in an opening aligned with the photo sensor, the first and second polysilicon layers having been implanted with impurities in separate processing steps.

### BRIEF DESCRIPTION OF THE DRAWINGS

Exemplary embodiments will be more clearly understood from the following detailed description taken in conjunction with the accompanying drawings. FIGS. 1 to 17 represent non-limiting, exemplary embodiments as described herein.

FIG. 1 is an equivalent circuit diagram for a unit cell of an image sensor in accordance with exemplary embodiments;

FIG. 2 is a cross-sectional view of a portion of an image sensor in accordance with exemplary embodiments;

FIGS. 3 to 13 are cross-sectional views illustrating stages of a method of manufacturing the image sensor of FIG. 2 in accordance with exemplary embodiments;

FIGS. 14 to 16 are cross-sectional views illustrating stages of a method of manufacturing the image sensor of FIG. 2 in accordance with exemplary embodiments; and

FIG. 17 is a block diagram illustrating an electronic system including an image sensor in accordance with exemplary embodiments.

### DESCRIPTION OF EMBODIMENTS

Various exemplary embodiments will be described more fully hereinafter with reference to the accompanying drawings, in which exemplary embodiments are shown. Exemplary embodiments may, however, be embodied in many different forms and should not be construed as limited to exemplary embodiments set forth herein. Rather, these exemplary embodiments are provided so that this disclosure will be thorough, and will convey the scope of exemplary embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. The term “or” is used in an inclusive sense unless otherwise indicated.

It will be understood that, although the terms first, second, third, for example. may be used herein to describe various elements, components, regions, layers and/or sections, these elements, components, regions, layers and/or sections should not be limited by these terms. These terms are only used to distinguish one element, component, region, layer or section from another region, layer or section. In this manner, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. In this manner, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. In this manner, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In this manner, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments in accordance with principles of inventive concepts will be explained in detail with reference to the accompanying drawings. exemplary embodiment exemplary embodiment exemplary embodiment

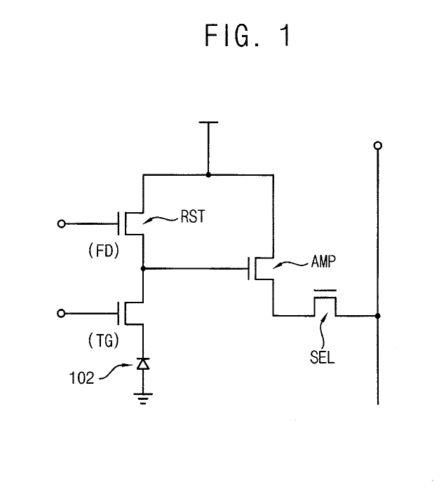

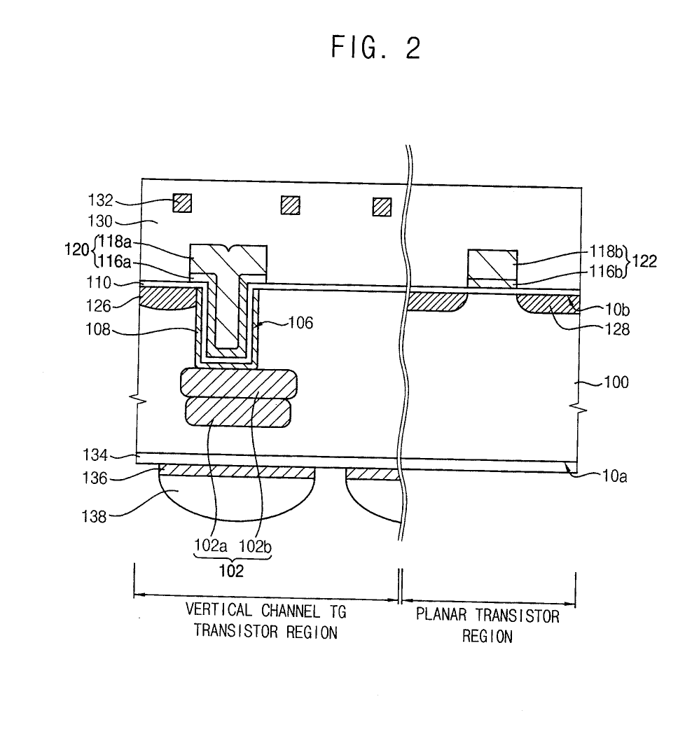

FIG. 1 is an equivalent circuit diagram of an exemplary embodiment of a unit cell of an image sensor in accordance with principles of inventive concepts. FIG. 2 is a cross-sectional view of a portion of an image sensor in accordance with principles of inventive concepts.

FIG. 2 shows a vertical channel transmission gate (TG) transistor region and a planar transistor region of a substrate 100. A transistor in the planar transistor region may be a pixel transistor or a peripheral circuit transistor, for example.

In exemplary embodiments, the image sensor of FIG. 2 may be a backside illumination (BSI) complementary metal oxide semiconductor (CMOS) image sensor (CIS).

Referring to FIGS. 1 and 2, the image sensor may include a photosensor such as a photodiode 102, a plurality of MOS transistors, a color filter 136 and a microlens 138. The MOS transistors, for example, may include a vertical channel transmission gate (TG) transistor, a reset (RST) transistor, an amplifier (AMP) transistor and a select (SEL) transistor.

Referring to FIG. 2, the substrate 100 may have a first surface 10a and a second surface 10b opposite the first surface 10a in a vertical direction, and may include a semiconductor material, for example, single crystalline silicon. The first surface 10a may be a front surface of the substrate 100, and the second surface 10b may be a rear surface of the substrate 100.

The photodiode 102 may be formed in an inner portion of the substrate 100 adjacent to the first surface 10a of the substrate 100 in the vertical channel TG transistor region, and may serve as a light receiver.

In exemplary embodiments, the photodiode 102 may include an n-type impurity region, which may be formed in each unit pixel. The n-type impurity region may have a structure in which a low concentration impurity region 102a and a high concentration impurity region 102b are sequentially stacked.

The color filter 136 and the microlens 138 may be formed on the first surface 10a of the substrate 100 in the vertical channel TG transistor region. MOS transistors and wirings (not shown, and also referred to herein as interconnections) may be formed on the second surface 10b of the substrate 100, which may be flat. The wirings may be formed on the MOS transistors.

The photodiode 102 may be electrically connected to an impurity region of the vertical channel TG transistor, for example, a source region (not shown) of the vertical channel TG transistor. In exemplary embodiments, the high concentration impurity region 102b of the photodiode 102 may also serve as the impurity region of the vertical channel TG transistor, and may be referred to herein as a first impurity region 102b of the vertical channel TG transistor.

In the vertical channel TG transistor, a channel may be formed in the vertical direction that may be perpendicular to the flat second surface 10b of the substrate 100.

In exemplary embodiments in accordance with principles of inventive concepts, a BSI image sensor may employ a vertical channel TG transistor with photodiode 102 formed adjacent to the first surface 10a of the substrate 100, which may be a rear surface of the substrate 100. Employing a vertical channel TG transistor in accordance with principles of inventive concepts may permit more efficient transfer of electrons from photodiode 102 than, for example, a planar transistor on the second surface 10b of the substrate 100.

The vertical channel TG transistor may include a gate insulation layer 110, a buried gate electrode 120, a first impurity region 102b, a second impurity region 126 and a third impurity region 108.

An opening 106 may be formed within the second surface 10b of the substrate 100, and a bottom surface of the opening 106 may be spaced apart from a top surface of the photodiode 102 in the vertical direction. That is, the opening 106 may vertically overlap, or lie above, the photodiode 102.

The gate insulation layer 110 may be conformally formed on an inner surface of the opening 106 and on the second surface 10b of the substrate 100.

The buried gate electrode 120 may fill the opening 106, and may vertically protrude from the second surface 10b of the substrate 100. The buried gate electrode 120 may include a structure in which a first polysilicon pattern 116a and a second polysilicon pattern 118a are sequentially stacked.

The first polysilicon pattern 116a may be conformally formed on portions of the gate insulation layer 110 that may be formed in the opening 106 and on the second surface 10b of the substrate 100.

The second polysilicon pattern 118a may be formed on the first polysilicon pattern 116a. The second polysilicon pattern 118a may fill the opening 106 in which the first polysilicon pattern 116a is formed, and protrude from the second surface 10b of the substrate 100 in the vertical direction. The first and second polysilicon patterns 116a and 118a may have a shape of the letter “T.”

The first polysilicon pattern 116a may be doped with n-type impurities by a first implantation process, which may be diffused after the first implantation process. The second polysilicon pattern 118a may be doped with n-type impurities by a second implantation process, which may be diffused after the second implantation process.

In accordance with principles of inventive concepts, buried gate electrode 120 including the first and second polysilicon patterns 116a and 118a sequentially stacked may have a substantially uniform impurity concentration. Because the impurity concentration of the buried gate electrode 120 may be substantially uniform, within a given range, throughout all areas thereof, no area therein exhibits resistive properties, or, in other words, has a resistive component due to a relatively low impurity concentration, the vertical channel TG transistor including the buried gate electrode 120 may transfer electrons more effectively than conventional transmission gate electrodes.

The second impurity region 126 may be formed at an upper portion of the substrate 100 adjacent to the buried gate electrode 120. The second impurity region 126 may be spaced apart from a sidewall of the buried gate electrode 120. The second impurity region 126 may also serve as a floating diffusion (FD) region in FIG. 1, and may be highly doped with n-type impurities.

The third impurity region 108 may be formed at a portion of the substrate 100 at which a channel of the vertical channel TG transistor may be formed. The third impurity region 108 may have a shallow depth from the opening 106. That is, third impurity region 108 may be formed along opening 106 to a relatively shallow depth. The third impurity region 108 may be doped with p-type impurities different from those of the first and second impurity regions 102b and 126.

The third impurity region 108 may have an impurity concentration higher than that of other portions of the substrate 100. In an exemplary embodiment, the third impurity region 108 may contact each of the first and second impurity regions 102b and 126. Due to the third impurity region 108, electrons may be prevented from leaking from the photodiode 102 when the vertical channel TG transistor is turned off. Third impurity region 108 may therefore be referred to as a leakage prevention impurity region.

The reset (RST) transistor, the amplifier (AMP) transistor and the select (SEL) transistor illustrated in the exemplary embodiment of FIG. 1 may be planar transistors. The peripheral circuit transistor may also be a planar transistor.

Each of the planar transistors may include the gate insulation layer 110, a gate electrode 122 and fourth impurities regions 128.

The gate insulation layer 110 and the gate electrode 122 may be foamed on the second surface 10b of the substrate 100.

The gate electrode 122 may include a third polysilicon pattern 116b and a fourth polysilicon pattern 118b sequentially stacked on the gate insulation layer 110. The third and fourth polysilicon patterns 116b and 118b may be doped with n-type impurities by the second implantation process, and diffused after the second implantation process. The fourth impurity regions 128 may serve as source and drain regions, respectively, and may be doped with n-type impurities.

As shown in the exemplary embodiment in accordance with principles of inventive concepts of FIG. 1, the second impurity regions 126, that is, the floating diffusion (FD) region may be electrically connected to an impurity region of the reset (RST) transistor and a gate electrode of the amplifier (AMP) transistor in FIG. 1. An impurity region of the amplifier AMP transistor may be electrically connected to an impurity region of the select (SEL) transistor. Another impurity region of the reset (RST) transistor and another impurity region of the amplifier (AMP) transistor may be electrically connected to a voltage drain drain (VDD) in FIG. 1. Another impurity region of the select (SEL) transistor may be electrically connected to a signal line in the exemplary embodiment of FIG. 1.

In an image sensor in accordance with exemplary embodiments, the vertical channel TG transistor may include a buried gate electrode 120 having uniform impurity concentration. Uniform impurity concentration of the buried gate electrode allows a vertical channel TG transistor in accordance with principles of inventive concepts to transfer electrons from photodiode 102 effectively and thereby reduce imperfections in an image sensor in accordance with principles of inventive concepts, such as distortion, fading and imaging noise.

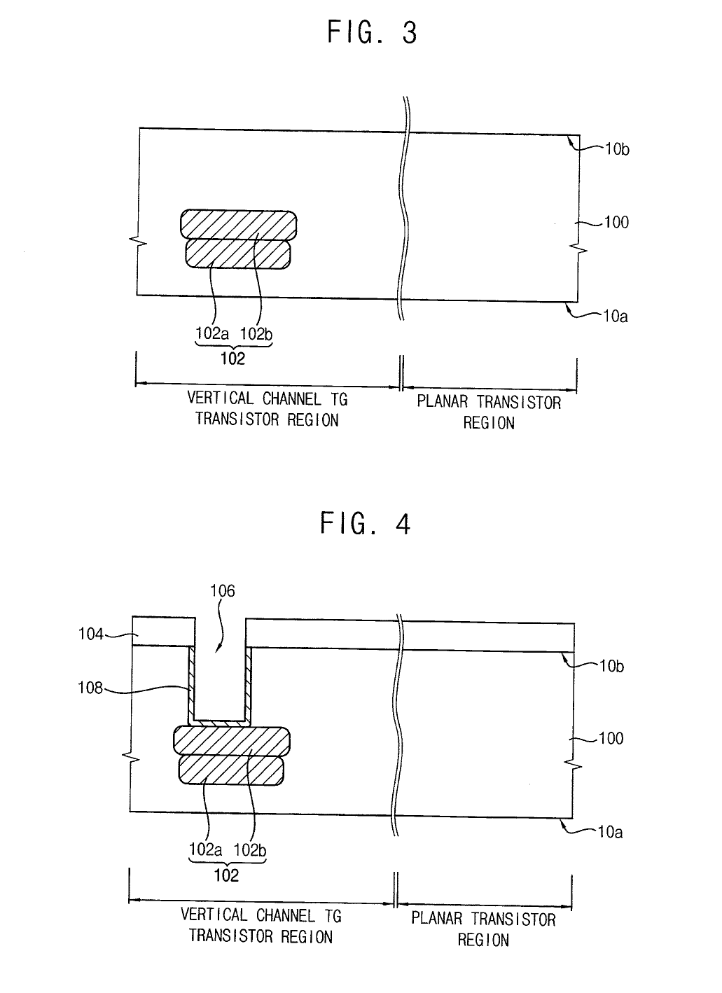

FIGS. 3 to 13 are cross-sectional views illustrating stages of a method of manufacturing an image sensor such as that of FIG. 2 in accordance with exemplary embodiments.

Referring to FIG. 3, a substrate 100 including a semiconductor material such as, for example, silicon, or germanium may be provided. The substrate 100 may be divided into a vertical channel transmission gate (TG) transistor region and a planar transistor region. The substrate 100 may include a first surface 10a and a second surface 10b, which may be referred to as a front surface and a rear surface, respectively, of the substrate 100.

N-type impurities may be implanted into the second surface 10b of the substrate 100 to form a photodiode 102. The photodiode 102 may be formed to include a low concentration impurity region 102a and a high concentration impurity region 102b sequentially stacked. The high concentration impurity region 102b close to the second surface 10b of the substrate 100 may be doped with n-type impurities more highly than the low concentration impurity region 102a close to the first surface 10a of the substrate 100.

Referring to FIG. 4, a mask 104 may be formed on the second surface 10b of the substrate 100. The mask 104 may expose a portion of the substrate 100 in which a buried gate electrode 120 (refer to FIG. 11) will be formed later. The substrate 100 may be anisotropically etched using the mask 104 as an etch mask to form an opening 106.

In exemplary embodiments in accordance with principles of inventive concepts the width and depth of a buried gate electrode 120 may be determined according to the shape of the opening 106.

A bottom surface of the opening 106 may be spaced apart from and opposite to a top surface of the photodiode 102 in a vertical direction that may be substantially perpendicular to the first and second surfaces 10a and 10b of the substrate 100. That is, the opening 106 may vertically align with, though not necessarily center-on, the photodiode 102.

P-type impurities may be implanted into an inner surface of the opening 106 to form third impurity region 108. The mask 104 may be formed on the second surface 10b of the substrate 100 so that the p-type impurities may be implanted into the inner surface of the opening 106 only. Third impurity region 108 may be formed to have a shallow depth from the inner surface of the opening 106 and may serve as a channel of the vertical channel TG transistor. In exemplary embodiments, the p-type impurities may be implanted through an ion implantation process and/or a plasma assisted implantation process, for example.

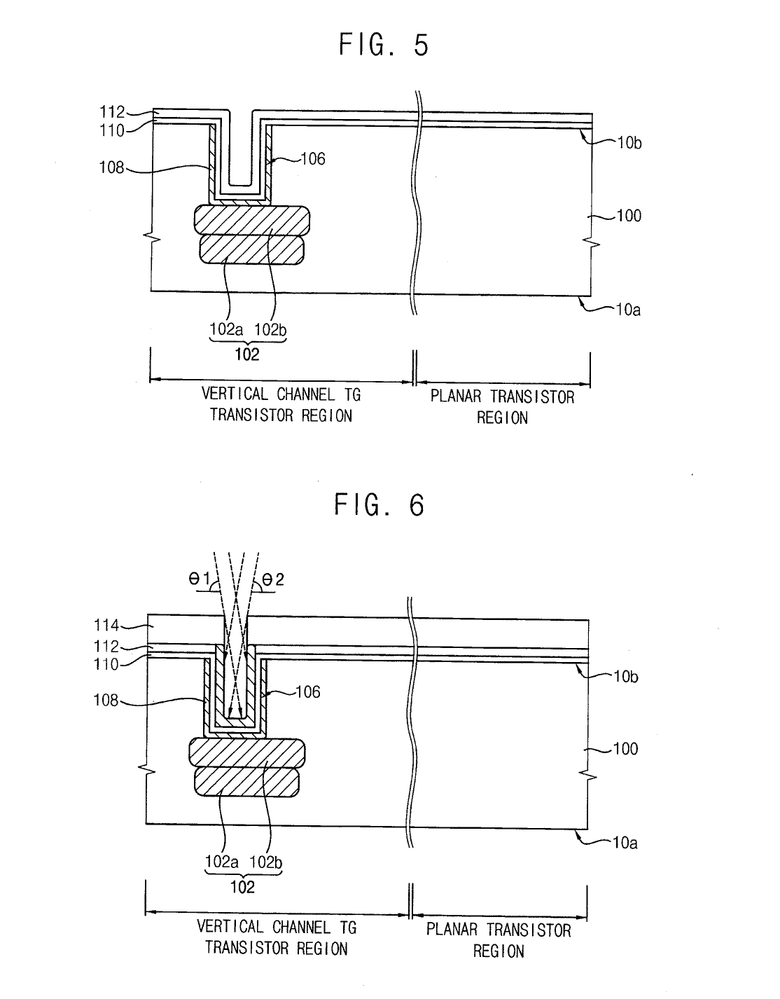

Referring to FIG. 5, the mask 104 may be removed to expose the second surface 10b of the substrate 100.

A gate insulation layer 110 may be conformally formed on the substrate 100 and the inner surface of the opening 106. The gate insulation layer 110 may include, for example, silicon oxide. In exemplary embodiments, gate insulation layer 110 may be formed by a deposition process or by a thermal oxidation process on the second surface 10b of the substrate 100.

A first preliminary polysilicon layer 112 that may not be doped with impurities (that is, that may remain unhoped) may be formed on the gate insulation layer 110.

The first preliminary polysilicon layer 112 may be conformally formed on the gate insulation layer 110 in a manner in which the first preliminary polysilicon layer 112 may not completely fill the opening 106. In exemplary embodiments, when the depth of the opening 106 is larger than the width of the opening 106, for example, the thickness of the first preliminary polysilicon layer 112 may be formed to be smaller than half of the width of the opening 106.

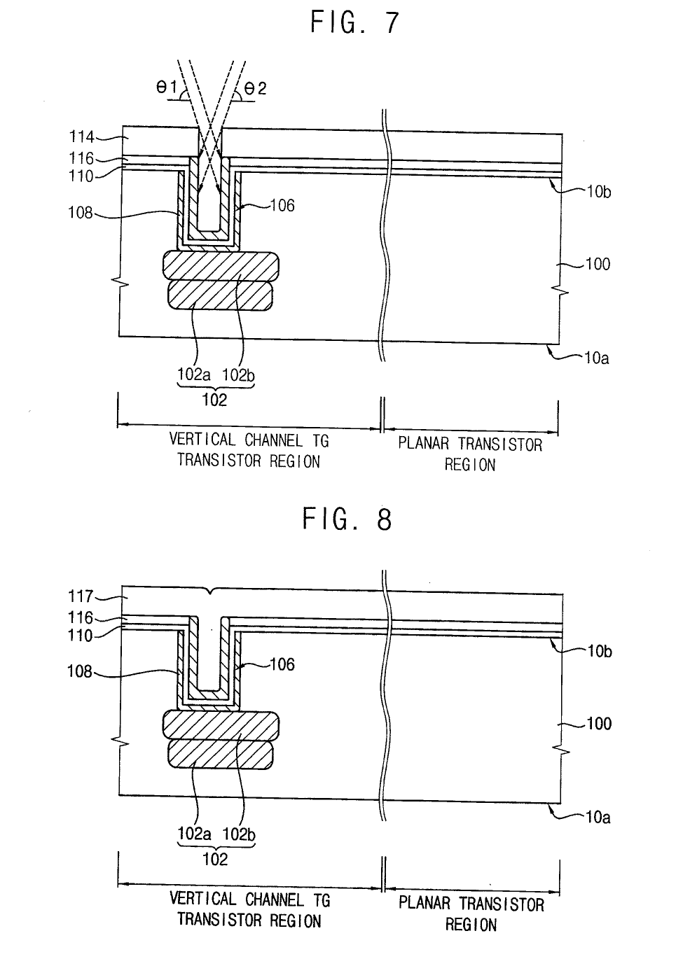

Referring to FIGS. 6 and 7, a first photoresist pattern 114 may be formed on the first preliminary polysilicon layer 112.

The first photoresist pattern 114 may serve as an ion implantation mask for selectively implanting n-type impurities into a portion of the first preliminary polysilicon layer 112 in the opening 106, and thus may be formed to expose the portion of the first preliminary polysilicon layer 112 in the opening 106 and cover other portions of the first preliminary polysilicon layer 112.

The first photoresist pattern 114 may be formed of sufficient thickness, so that the impurities may not be implanted into a portion of the first preliminary polysilicon layer 112 that may be beneath the first photoresist pattern 114 and on the second surface 10b of the substrate 100.

A first doping process may be performed onto the first preliminary polysilicon layer 112 to form a first polysilicon layer 116 partially doped with n-type impurities.

In exemplary embodiments, the first doping process may include a plurality of ion implantation processes using the first photoresist pattern 114 (see FIG. 6, for example) as an ion implantation mask. Implantation angles of ions of the n-type impurities with respect to the bottom surface of the opening 106 may be different in the plurality of ion implantation processes, respectively. Hereinafter, only the case in which the first doping process includes two ion implantation processes having two implantation angles from each other will be illustrated. The implantation angles may be acute angles with respect to the bottom surface of the opening 106.

Referring to FIG. 6, n-type impurities may be implanted into the first preliminary polysilicon layer 112 at a first implantation angle θ₁. The n-type impurities may not be implanted into a portion of the first preliminary polysilicon layer 112 on which the first photoresist pattern 114 is formed or which is shadowed by photoresist pattern 114, but may be implanted into only a portion of the first preliminary polysilicon layer 112 in the opening 106 left exposed by photoresist pattern 114, taking into account shadowing at the angle θ₁.

Referring to FIG. 7, n-type impurities may be implanted into the first preliminary polysilicon layer 112 at a second implantation angle θ₂. The second implantation angle θ₂ may be different from the first implantation angle θ₁ and, in exemplary embodiments, may implant regions of polysilicon layer 112 not implanted from angle θ₁.

In accordance with principles of inventive concepts, the preliminary first polysilicon layer 112 may be converted into the first polysilicon layer 116 by a plurality of ion implantation processes from different angles.

The first and second implantation angles θ₁ and θ₂ may be adjusted in order to form the first polysilicon layer 116 having a uniform concentration of ions. A first portion of the first preliminary polysilicon layer 112 in the opening 106 may be doped through the first ion implantation process having the first implantation angle θ₁, and a second portion of the first preliminary polysilicon layer 112 may be doped through the second ion implantation process having the second implantation angle θ₂.

In exemplary embodiments, the first implantation angle θ₁ may be adjusted so that the impurities may be implanted into almost all of the bottom surface and a lower sidewall of the opening 106, and the second implantation angle θ₂ may be adjusted so that the impurities may be implanted into almost all of an upper sidewall of the opening 106, for example. In such embodiments, the second implantation angle θ₂ may be smaller than the first implantation angle θ₁.

The first and second angles θ₁ and θ₂ may be adjusted in consideration of an aspect ratio of the opening 106. As the aspect ratio of the opening 106 increases, the number of performance of the ion implantation process, that is, the number of the implantation angles and associated ion implantation processes, may increase in order to assure uniform doping.

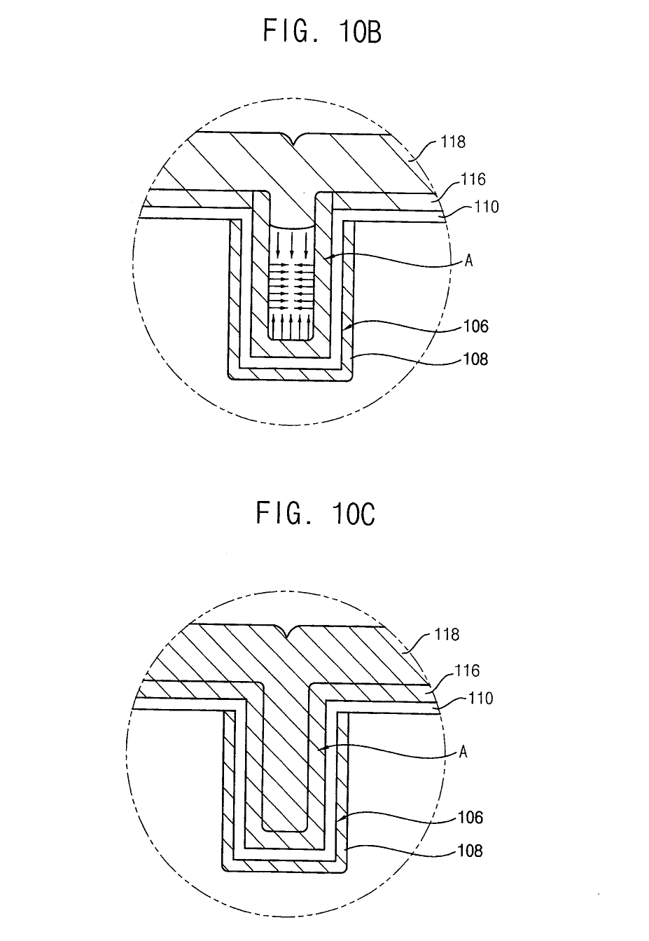

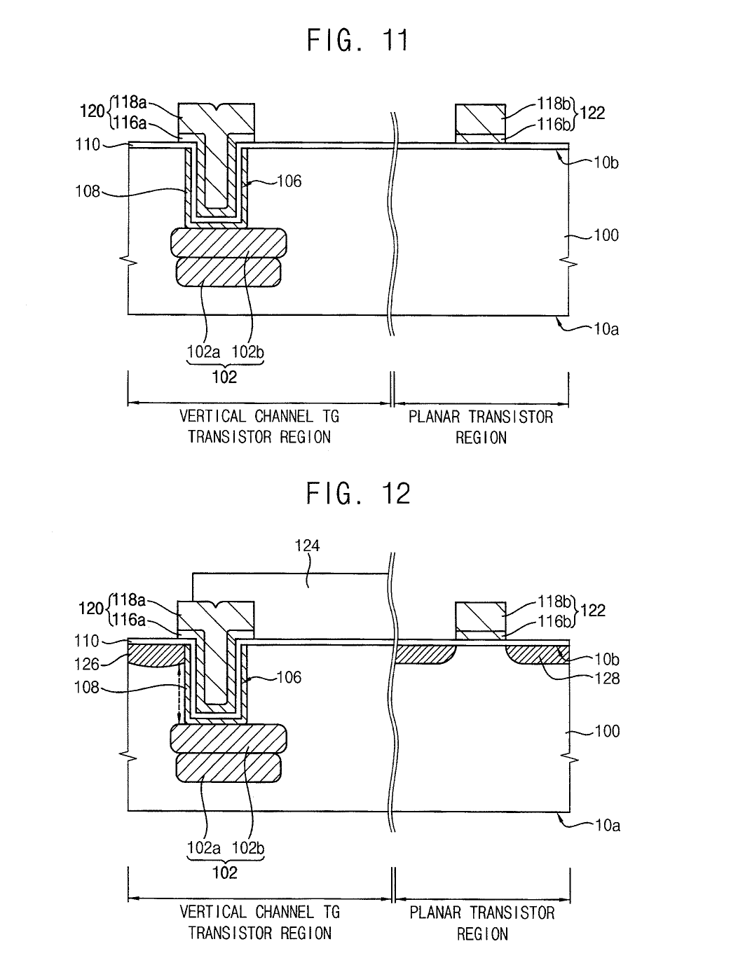

FIG. 10A illustrates a doping profile of the portion of the first polysilicon layer 116 in the opening 106 after an exemplary first doping process.

The first doping process may include a plurality of implantation processes having different implantation angles from each other. Therefore, as illustrated in FIG. 10A, even if the aspect ratio of the opening 105 is high, the portion of the first polysilicon layer 116 in the opening 106 may have a uniform first doping area A.

In the first doping process, the first doping area A of the first polysilicon layer 116 may have a desired depth by controlling the implantation angle, and thus the n-type impurities may not be implanted into a portion of the substrate 100 under the bottom surface or the lower sidewall of the opening 106. Therefore, even if the first doping process is performed, the concentration of the impurities of the third impurity region 108 may not be changed. That is, in accordance with principles of inventive concepts, by employing multiple doping steps using different doping angles substantially uniform doping of first polysilicon layer 116 may be achieved without over-doping or otherwise modifying the concentration of impurities in third doping impurity region 108.

Referring to FIG. 8, the first photoresist pattern 114 may be removed, and a second unhoped preliminary polysilicon layer 117 may be formed on the first polysilicon layer 116.

The second preliminary polysilicon layer 117 may be formed to fill a remaining portion of the opening 106 and have a given thickness on the second surface 10b of the substrate 100. A top surface of the second preliminary polysilicon layer 117 may become a top surface of the buried gate electrode 120 of the vertical channel TG transistor and a top surface of a gate electrode 122 (refer to FIG. 11) of a planar transistor.

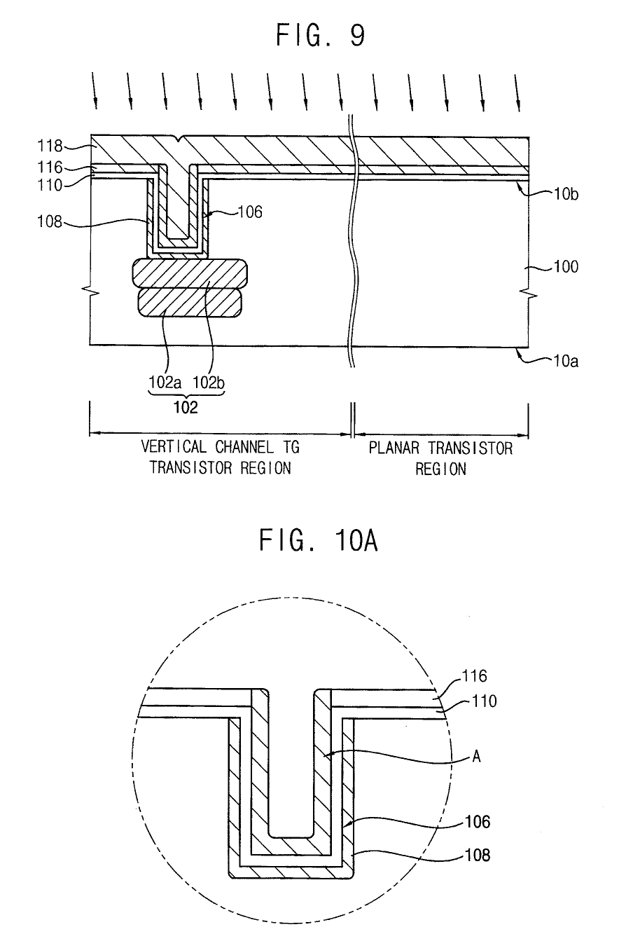

Referring to FIG. 9, a second doping process may be performed on the second preliminary polysilicon layer 117 to form a second polysilicon layer 118 doped with n-type impurities. The second doping process may be performed with no ion implantation mask so that the n-type impurities may be implanted into an entire portion of the second preliminary polysilicon layer 117, for example.

In exemplary embodiments, the second doping process may include a single implantation process, and ions of n-type impurities may thereby be implanted into the second polysilicon layer 118 at a single implantation angle.

The n-type impurities may be also implanted into the first polysilicon layer 116 on the second surface 10b of the substrate 100 during the second doping process. However, a portion of the substrate 100 under the second surface 10b may be left unhoped.

FIG. 10B illustrates a doping profile of the first and second polysilicon layers 116 and 118 in the opening 106 after the second doping process. FIG. 10C illustrates the first and second polysilicon layers 116 and 118 when the impurities are diffused after the second doping process.

As illustrated in FIG. 10B, in exemplary embodiments in accordance with principles of inventive concepts, impurities may not be implanted into a portion of the second polysilicon layer 118 at a center of the opening 106.

An annealing process may be performed so that the doped impurities may be diffused into the first and second polysilicon layers 116 and 118. In exemplary embodiments, the annealing process may be independently performed for the first and second polysilicon layers. Alternatively, the annealing process may not be performed, however, in such embodiments, the impurities may be diffused into the first and second polysilicon layers 116 and 118 due to heat generated in a deposition process and/or an etch process subsequently performed, for example.

The doped impurities may be diffused into the first and second polysilicon layers 116 and 118 from all directions in the annealing process. Therefore, as illustrated in FIG. 10C, the impurities may be uniformly diffused into the first and second polysilicon layers 116 and 118.

Some of the doped impurities in the first polysilicon layer 116 may be diffused into the second polysilicon layer 118 through the annealing process. In addition, some of the doped impurities in an upper portion of the second polysilicon layer 118 may be diffused into a lower portion of the second polysilicon layer 118 through the annealing process. In this manner, in accordance with principles of inventive concepts, doped impurities may be diffused into a portion of the second polysilicon layer 118 in the center of the opening 106.

If impurities are not uniformly doped in the first polysilicon layer 116, a non-uniform impurity region may be formed in the structure in which the first and second polysilicon layers 116 and 118 are sequentially stacked, even after performing the annealing process. For example, if the first polysilicon layer 116 includes a portion of which an impurity concentration is lower than that of the other portions thereof, impurities may not be sufficiently diffused into the portion of the second polysilicon layer 118 in the center of the opening 106. Therefore, a non-uniform impurity region may be formed in the structure in which the first and second polysilicon layers 116 and 118 are sequentially stacked. However, in exemplary embodiments in accordance with principles of inventive concepts impurities may be uniformly doped into the first polysilicon layer 116 and, as a result, impurities may be sufficiently diffused into the second polysilicon layer 118 through the annealing process. For example, the impurities may be easily diffused into the portion of the second polysilicon layer 118 in the center of the opening 106, and, as a result, the concentration of the impurities may be uniform in the first and second polysilicon layers 116 and 118.

The impurities doped in a portion of the second polysilicon layer 118 on the second surface 10b of the substrate 100 may be diffused into a portion of the first polysilicon layer 116 on the second surface 10b of the substrate 100 through the annealing process. Thus, the portion of the first polysilicon layer 116 on the second surface 10b of the substrate 100 may be uniformly doped by the second doping process and/or the annealing process in accordance with principles of inventive concepts.

Referring to FIG. 11, the first and second polysilicon layers 116 and 118 may be partially etched using an etch mask (not shown) to form the buried gate electrode 120 and the gate electrode 122 on the substrate 100.

The buried gate electrode 120 may have a structure in which a first polysilicon pattern 116a and a second polysilicon pattern 118a are sequentially stacked. The buried gate electrode 120 may be formed to vertically extend from the opening 106 and protrude from the second surface 10b of the substrate 100. The first and second polysilicon patterns 116a and 118a may have a shape of the letter “T,” with the overall outline of first polysilicon pattern 116a having the shape of a “T,” but hollowed-out, as illustrated. The buried gate electrode 120 may serve as a gate electrode of the vertical channel TG transistor.

The gate electrode 122 may have a structure in which a third polysilicon pattern 116b and a fourth polysilicon pattern 118b are sequentially stacked. The gate electrode 122 may be formed on the second surface 10b of the substrate 100. The gate electrode 122 may serve as a gate electrode of a planar transistor.

As illustrated, in accordance with principles of inventive concepts buried gate electrode 120 and gate electrode 122 may be uniformly implanted with n-type impurities and regions of the substrate 100 under buried gate electrode 120 and gate electrode 122 may be left unhoped (that is, not implanted with n-type impurities).

Referring to FIG. 12, a second photoresist pattern 124 may be formed on the second surface 10b of the substrate 100 to expose at least a portion of the gate insulation layer 110 on the second surface 10b of the substrate 100 adjacent to the buried gate electrode 120.

N-type impurities may be implanted into an upper portion of the substrate 100 through the exposed portion of the gate insulation layer 110 to form a floating diffusion (FD) region 126. Then, the second photoresist pattern 124 may be removed.

An ion implantation process may be performed to form fourth impurity regions 128 at upper portions of the substrate 100 adjacent to the gate electrode 122 in the planar transistor region. The fourth impurity regions 128 may serve as source and drain regions of the planar transistor.

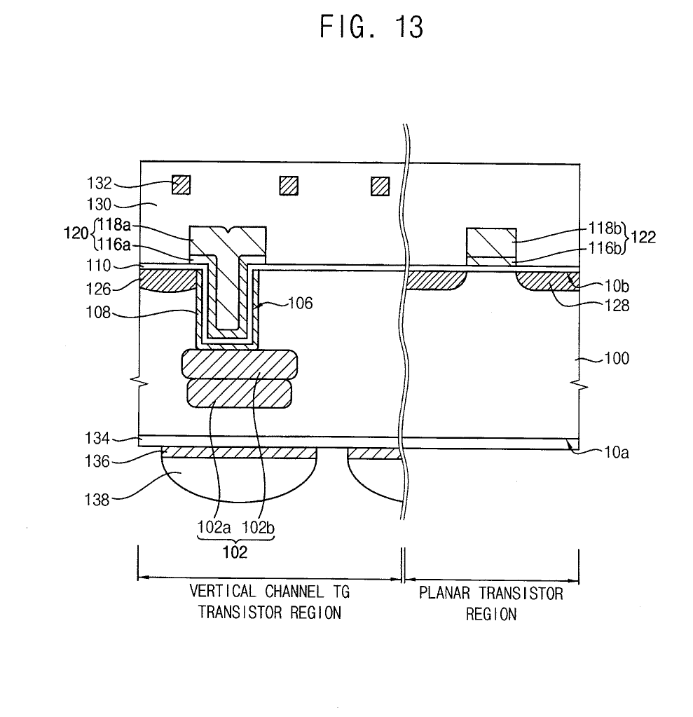

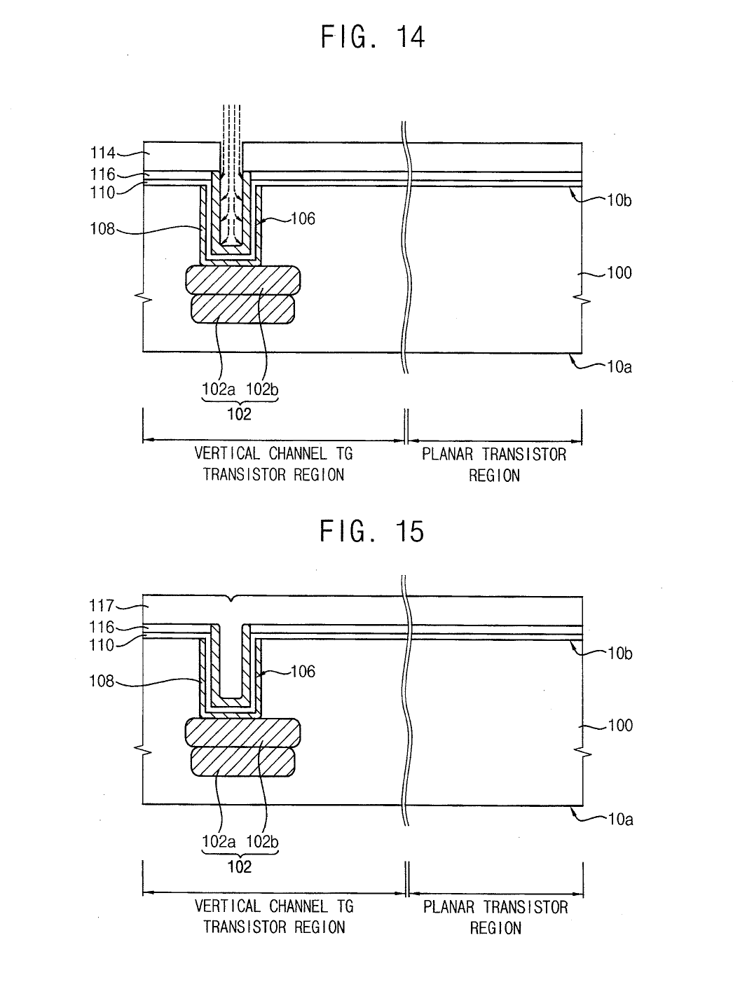

Referring to FIG. 13, an insulating interlayer 130 may be formed on the substrate 100 to cover the vertical channel TG transistor and the planar transistor. Wirings 132 may be formed in the insulating interlayers 130.

A portion of the substrate 100 adjacent to the first surface 10a may be partially etched so that a thickness of the substrate 100 may be reduced. An anti-reflective layer 134 may be formed on the first surface 10a of the substrate 100. A color filter 136 and a microlens 138 may be sequentially formed on the anti-reflective layer 134.

The image sensor formed through the above processes may include a vertical channel TG transistor in accordance with principles of inventive concepts. The buried gate electrode 120 of the vertical channel TG transistor may be uniformly doped with impurities so that electrons may be easily transferred through the vertical channel TG transistor, thereby reducing imperfections that may otherwise be incurred by an image sensor, such as, for example, distortion, fading and imaging noise.

FIGS. 14 to 16 are cross-sectional views illustrating stages of a method of manufacturing the image sensor of FIG. 2 in accordance with exemplary embodiments.

This exemplary method may include processes substantially the same as or similar to those illustrated with reference to FIGS. 3 to 13, except for the first and second doping processes. Processes substantially the same as or similar to those illustrated with reference to FIGS. 3 to 5 may be performed to form the structure of FIG. 5.

Referring to FIG. 14, a first photoresist pattern 114 may be formed on the first preliminary polysilicon layer 112. The first photoresist pattern 114 may expose a portion of the first preliminary polysilicon layer 112 within opening 106 and cover other portions of the first preliminary polysilicon layer 112.

A first doping process may be performed on the first preliminary polysilicon layer 112 using the first photoresist pattern 114 as an ion implantation mask to form a first polysilicon layer 116 in which n-type impurities may be partially doped.

In exemplary embodiments, the first doping process may be performed by a plasma assisted doping process. In this case, the first doping process may be performed using a single implantation process.

In the first doping process, an n-type impurity source gas may be provided into a chamber (not shown). A voltage pulse may be applied to the chamber, and plasma may be generated at a portion of the chamber adjacent to the substrate 100. Ions in the plasma may be accelerated towards the substrate 100 by the voltage pulse so as to be absorbed and/or implanted into the portion of the first preliminary polysilicon layer 112 in the opening 106, and may be diffused therein.

In exemplary embodiments in accordance with principles of inventive concepts, first preliminary polysilicon layer 112 may be formed to have a thickness less than half the width of the opening 106, for example. In the first doping process in accordance with principles of inventive concepts, n-type impurities are uniformly doped in the first preliminary polysilicon layer 112, and are doped with a given depth so as not to be diffused into a portion of the substrate 100 under the bottom surface or the lower sidewall of the opening 106.

The plasma assisted doping process may be performed with energy lower than other ion implantation processes such as, for example, a beam line ion implantation process. As a result, the doping depth of the n-type impurities may be relatively shallow, and the doping profile in the first preliminary polysilicon layer 112 may be uniform, even if the aspect ratio of the opening 106 is relatively high. In this manner, in accordance with principles of inventive concepts, the portion of the first polysilicon layer 116 in the opening 106 may have a uniform doping area by a single performance of the plasma assisted doping process.

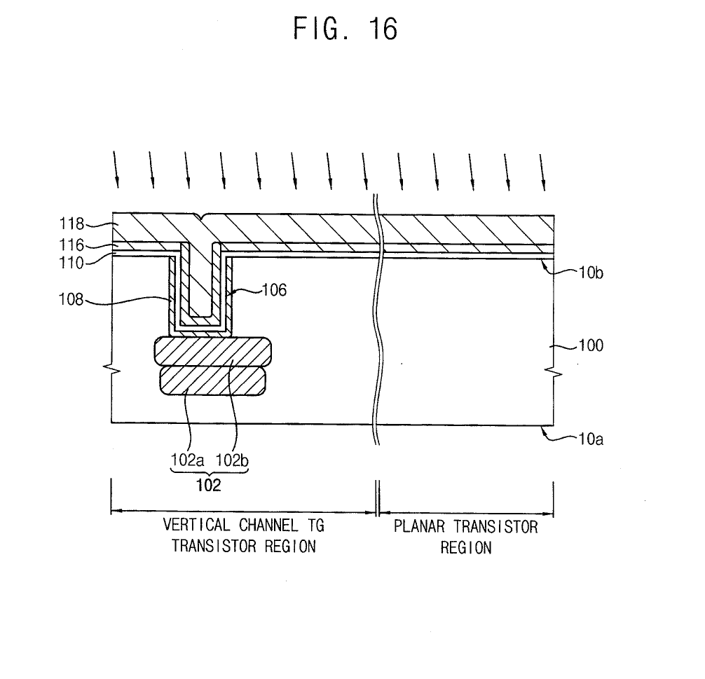

Referring to FIG. 15, the first photoresist pattern 114 may be removed, and a second preliminary polysilicon layer 117, which may not be doped with impurities, may be formed on the first polysilicon layer 116. The second preliminary polysilicon layer 117 may be formed to fill a remaining portion of the opening 106 and have a given thickness on a second surface 10b of the substrate 100.

The top surface of the second preliminary polysilicon layer 117 may become the top surface of the buried gate electrode 120 (refer to FIG. 2) of a vertical channel TG transistor and the top surface of a gate electrode 122 (refer to FIG. 2) of a planar transistor.

Referring to FIG. 16, a second doping process may be performed on the second preliminary polysilicon layer 117 to form a second polysilicon layer 118 doped with n-type impurities. The second doping process may be performed with no ion implantation mask so that the n-type impurities may be implanted into an entire portion of the second preliminary polysilicon layer 117.

In exemplary embodiments, the second doping process may be performed with a single implantation process, and thus ions of the n-type impurities may be implanted into the second polysilicon layer 118 at a single implantation angle.

The n-type impurities may be also implanted into the first polysilicon layer 116 on the second surface 10b of the substrate 100 during the second doping process. The portion of the substrate 100 under second surface 10b may be left un-implanted.

Alternatively, the second doping process may be performed by a plasma assisted doping process.

An annealing process may be performed so that the doped impurities may be diffused into the first and second polysilicon layers 116 and 118. Then, processes substantially the same as or similar to those illustrated with reference to FIGS. 11 to 13 may be performed to form the image sensor of FIG. 2.

The image sensor formed through the above processes may include a vertical channel TG transistor in accordance with principles of inventive concepts. The buried gate electrode 120 of the vertical channel TG transistor may be uniformly doped with impurities so that electrons may be easily transferred through the vertical channel TG transistor, thereby reducing imperfections that may otherwise be incurred by an image sensor, such as, for example, distortion, fading and imaging noise.

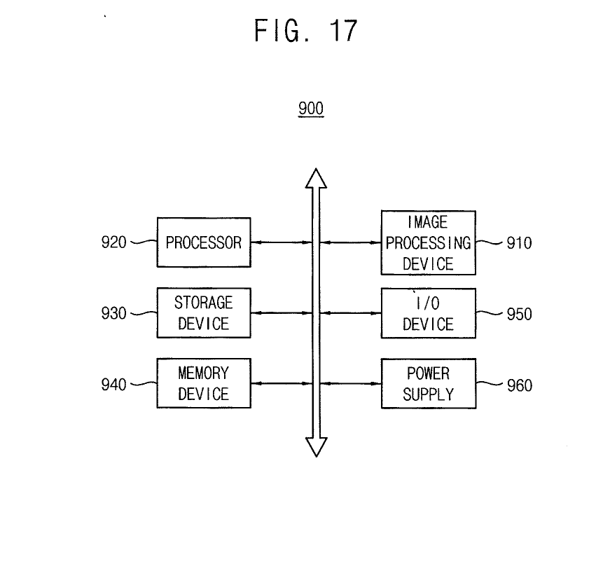

FIG. 17 is a block diagram illustrating an exemplary embodiment of an electronic system including an image sensor in accordance with principles of inventive Electronic system 900 may include an image sensor 910, a processor 920 and a storage device 930.

The image sensor 910 may generate a digital signal corresponding to a light incident thereon. The storage device 930 may store the digital signal. The processor 920 may control operation of the electronic system 900.

The electronic system 900 may include a memory device 940, an input/output device 950 and a power device 960. In addition, the electronic system 900 may further include a plurality of ports which may communicate with, for example, a video card, a sound card, a memory card, a USB device, etc.

The processor 920 may perform calculations, control, or other tasks. In exemplary embodiments, the processor 920 may be a microprocessor or a central processing unit (CPU). The processor 920 may be electrically connected to the storage device 930, the memory device 940, the input/output device 950 via an address bus, a control bus and a data bus. In exemplary embodiments, the processor 920 may be electrically connected to an extension bus, for example, a peripheral component interconnect (PCI) bus.

The storage device 940 may include, for example, a flash memory device, a solid state device (SDD), a hard disk drive (HDD), a CD-ROM or any form of a non-volatile memory device, for example.

The memory device 940 may store data required for the operation of the electronic system 900. The memory device 940 may include a volatile memory device, for example, a dynamic random access memory (DRAM), a static random access memory (SRAM), etc., or a non-volatile memory device, for example, an erasable programmable read-only memory (EPROM), an electrically erasable programmable read-only memory (EEPROM), a flash memory device, etc.

The input/output device 950 may include an input device, for example, a keyboard, a keypad, a mouse, etc., or an output device, for example, a printer, a display monitor, etc. The power device 960 may supply an operation voltage required for the operation of the electronic system 900.

The image sensor 910 may be electrically connected to the processor 920 via the buses or other links.

The image sensor 910 may be a BSI CMOS image sensor, which may include a vertical channel TG transistor. The image sensor 910 may include, for example, a package on package (POP), a ball grid arrays (BGAs), a chip scale packages (CSPs), a plastic leaded chip carrier (PLCC), a plastic dual in-line package (PDIP), a die in waffle pack, a die in wafer form, a chip on board (COB), a ceramic dual in-line package (CERDIP), a plastic metric quad flat pack (MQFP), a thin quad flat pack (TQFP), a small outline (SOIC), a shrink small outline package (SSOP), a thin small outline (TSOP), a thin quad flat pack (TQFP), a system in package (SIP), a multi-chip package (MCP), a wafer-level fabricated package (WFP) and a wafer-level processed stack package (WSP), etc.

In exemplary embodiments, the image sensor 910 may be integrally formed in a unit chip with the processor 920. Alternatively, each of the image sensor 910 and the processor 920 may be formed in chips, respectively.

The electronic system 910 may be a device using the image sensor 910. For example, the electronic system 910 may be a digital camera, a mobile phone, a personal digital assistant (PDA), a portable multimedia player (PMP), a smart phone, etc.

The image sensor 910 may be included in any electrical device that may include an image sensor. The image sensor 910 may be included in, for example, a mobile phone, a smart phone, a personal digital assistant (PDA), a digital camera, a personal computer (PC), a server computer, a workstation, a laptop, a digital television, etc.

The foregoing description is illustrative of exemplary embodiments and is not to be construed as limiting thereof. Although exemplary embodiments have been described, those skilled in the art will readily appreciate that many modifications are possible in the exemplary embodiments without materially departing from the novel teachings and advantages of inventive concepts. Accordingly, all such modifications are intended to be included within the scope of inventive concepts as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A method of manufacturing an image sensor, comprising:
forming a photodiode in a substrate;
etching a portion of the substrate to form an opening vertically aligned with the photodiode;
forming a gate insulation layer and a first preliminary polysilicon layer on an inner surface of the opening and a front surface of the substrate;
performing a first doping process on the first preliminary polysilicon layer to form a first polysilicon layer, a portion of the first polysilicon layer in the opening being uniformly doped with impurities of a first conductivity type;
forming a second preliminary polysilicon layer on the first polysilicon layer;
performing a second doping process on the second preliminary polysilicon layer to form a second polysilicon layer, the second polysilicon layer being doped with impurities of the first conductivity type;
patterning the first and second polysilicon layers to form a buried gate electrode in the opening; and
forming a first impurity region at an upper portion of substrate adjacent to the buried gate electrode.

2. The method of claim 1, wherein the first doping process includes a plurality of implantation processes having different implantation angles with respect to a bottom surface of the opening.

3. The method of claim 2, wherein the first doping process includes a first ion implantation process and a second ion implantation process, and wherein a first portion of the first preliminary polysilicon layer is implanted at a first implantation angle by the first ion implantation process, and a second portion of the first preliminary polysilicon layer is implanted at a second implantation angle by the second ion implantation process.

4. The method of claim 1, wherein the first doping process is performed by a plasma assisted implantation process.

5. The method of claim 1, wherein a bottom surface of the opening is spaced apart from a top surface of the photodiode.

6. The method of claim 1, further comprising forming a leakage prevention impurity region in the substrate by implanting impurities of a second conductivity type opposite to the first conductivity type into a portion of the substrate under the opening.

7. The method of claim 1, wherein, prior to performing the first doping process, further comprising:
forming an ion implantation mask on the first preliminary polysilicon layer, the ion implantation mask exposing a portion of the first preliminary polysilicon layer over the opening.

8. The method of claim 1, further comprising performing an annealing process to diffuse the impurities of the first conductive type doped in the first and second polysilicon layers.

9. The method of claim 1, wherein patterning the first and second polysilicon layers includes forming a gate electrode on the front surface of the substrate.

10. The method of claim 9, further comprising forming second impurity regions at upper portions of the substrate adjacent to the gate electrode.

11. The method of claim 1, wherein the second doping process includes a single implantation process.

12. The method of claim 1, wherein the second doping process is performed by a plasma assisted implantation process.

13. The method of claim 1, wherein the impurities are not doped into a portion of the substrate under a bottom surface of the opening in the first doping process.

14. The method of claim 1, wherein the impurities are not doped into a portion of the substrate under the front surface of the substrate in the second doping process.

15. The method of claim 1, after forming the first impurity region, further comprising:
forming an insulating interlayer to cover the buried gate electrode on the substrate;
forming wirings in the insulating interlayer; and
sequentially forming a color filter and a microlens on a rear surface of the substrate, wherein the rear surface of the substrate is vertically opposite to the front surface of the substrate.

16. A back side illumination CMOS image sensor, comprising:
a microlens formed on a substrate;
a photo sensor formed in the substrate to receive electrical signals in response to light received through the microlens; and
a vertical channel transmission gate transistor to transfer electrical signals from the photo sensor, the vertical channel including first and second polysilicon layers formed in an opening aligned with the photo sensor, the first and second polysilicon layers having been implanted with impurities in separate processing steps.

17. The image sensor of claim 16, wherein the first polysilicon layer has been implanted from a plurality of angles.

18. The image sensor of claim 16, wherein the first polysilicon layer has been implanted using a plasma assisted ion doping process.

19. An electrical system including the image sensor of claim 16.

20. The electrical system of claim 19 including a smart phone.
